(19) United States
(12) Patent Application Publication
(10) Pub. No.: US 2002/0139979 A1
(43) Pub. Date: Oct. 3, 2002

(54) Method of crystallizing a silicon layer and method of fabricating a semiconductor device using the same

(76) Inventors: Seung Ki Joo, Seongnam-si (KR); Seok-Woon Lee, Incheon (KR)

Correspondence Address: BAKER & BOTTS, 30 ROCKEFELLER PLAZA, NEW YORK, NY, 10112

(21) Appl. No.: 10/113,352

(22) Filed: Apr. 1, 2002

(30) Foreign Application Priority Data
Mar. 30, 2001 (KR) 2001-16924

(51) Int. Cl. H01L 21/00; H01L 21/84; H01L 29/04; H01L 29/76

(52) U.S. Cl. 257/70; 438/166; 438/154; 438/479

(57) ABSTRACT

The present invention provides a method for increasing a crystallization rate of an amorphous silicon layer by implanting boron into the amorphous silicon layer during a process of crystallizing the silicon layer, which is used for an active layer of a thin film transistor, using MIC or MILC phenomenon. The method of crystallizing the silicon layer according to the present invention can be effectively utilized for fabricating P-type, N-type or CMOS thin film transistors.

### BACKGROUND OF THE INVENTION

1. Field of the Invention

The present invention relates to a method of crystallizing a silicon layer and a method of fabricating a semiconductor device using the crystalline silicon layer. More specifically, the present invention relates to a thin film transistor (TFT) for use in a display device such as a liquid crystal display (LCD) and an organic light emitting diode (OLED), and more particularly, to a thin film transistor in which an active layer for constituting source and drain regions and a channel is formed out of a crystalline silicon and a method of fabricating the thin film transistor.

2. Description of the Prior Art

A thin film transistor for use in a display device such as LCD and OLED is usually constructed in such a manner that silicon is deposited on a transparent substrate made of glass, quartz, or the like; gates and gate electrodes are formed thereon; dopants are implanted into source and drain regions and are activated in a process of annealing; and then an insulating layer is formed thereon. An active layer for constituting the source and drain regions and a channel of the thin film transistor is generally formed by depositing a silicon layer onto the transparent substrate made of glass using a chemical vapor deposition (CVD) method. However, the silicon layer deposited directly onto the substrate by using a method such as the CVD is an amorphous silicon layer, and thus, has low electron mobility. As the display device employing the thin film transistors requires a fast operating speed and is miniaturized, the degree of integration of driving integrated circuits (ICs) is increased and an aperture ratio of a pixel area is decreased. Thus, it is necessary to simultaneously form the driving circuits and the pixel TFTs and to increase the pixel aperture ratio by improving the electron mobility of the silicon layer. To this end, a technique for forming a crystalline silicon layer having, high electron mobility by means of crystallization of the amorphous silicon layer through the annealing thereof has been utilized.

Various techniques for crystallizing the amorphous silicon layer into the crystalline silicon layer of the thin film transistor have been proposed. Solid phase crystallization (SPC) is a method for annealing the amorphous silicon layer for several hours to several tens of hours at a temperature of about 70° C. or lower that is a transition temperature of glass used for forming the substrate of the display device employ the thin film transistor. Since the SPC method requires a long period of time for thermal annealing the silicon layer, there is a problem in that productivity thereof is low. Further, if the substrate has a large area, the substrate may be deformed during the process of long thermal annealing even at a temperature of 600° C. or lower. Excimer laser crystallization is a method for instantaneously crystallizing the silicon layer by scanning the silicon layer using the excimer laser beam onto to generate high temperature thereon locally for a very short period of time. The ELC method has a technical difficulty in precisely controlling the scanning of the laser beam and can fabricate only one substrate at one time. Therefore, there is also a problem in that productivity of the ELC method becomes lower than a case where several substrates are batch processed in a furnace.

In order to overcome the shortcoming of the conventional method for crystallizing the silicon layer, it is utilized a phenomenon in which a phase change of the amorphous silicon into the polysilicon is induced even at a low temperature of about 200° C. when metals such as nickel, palladium, gold and aluminum come into contact with or implanted into the amorphous silicon. Such a phenomenon is called as metal induced crystallization (MIC). In a case where the thin film transistor has been fabricated using the MIC phenomenon, any metal remains in the polysilicon for constituting the active layer of the thin film transistor. Thus, there is a problem in that current leakage occurs particularly at the channel of the thin film transistor. Recently, instead of the method of inducing the crystallization of the silicon by means of the metals which come into direct contact with or are implanted into the silicon like the MIC method, there has been proposed a method for crystallizing the silicon layer using metal induced lateral crystallization (MILC) in which crystallization of the silicon is successively induced while silicide formed by reaction of the metal and silicon is continuously, laterally propagated (S. W. Lee & S. K. Joo, IEEE Electron Device Letter, 17(4), p.160, 1996). Nickel, palladium, and the like are specifically known as the metals for inducing the MILC. In a case where the silicon layer is crystallized using the MILC, a metal component used for inducing the crystallization of the silicon hardly remains within the silicon layer, which is crystallized through the MILC, since an interface of the metal-containing silicide moves laterally as the crystallization of the silicon layer is propagated. Thus, there is an advantage in that the metals such as Ni and Pd have no influence on the current leakage characteristics and other operating characteristics of the active layer of the thin film transistor. In addition, by utilizing the MILC, the crystallization of the silicon can be induced even at a relatively low temperature of 300° C. to 500° C. Thus, there is another advantage in that the furnace can be used so that several sheets of the substrates are simultaneously crystallized without damage to the substrates. Further, according to the method, the problems such as the non-uniformity of the crystallization and the decrease in yield, which are problems produced in the crystallization method using the laser, can be greatly solved. However, thermal annealing should be made at a temperature of about 500° C. during several hours if the method is to be applied to an actual process. Therefore, it is required to effectively reduce the time to perform the thermal annealing for crystallization of the silicon in the silicon crystallization method using the MILC.

### SUMMARY OF THE INVENTION

An object of the present invention is to provide a method for improving a crystallization rate of silicon by controlling kinds and doping concentrations of impurities implanted into the silicon, on the basis of the facts that the crystallization rate of the silicon using MIC or MILC is influenced by the kinds and concentrations of the impurities implanted into the silicon, for solving the problem that a crystallization method of the silicon using MILC requires thermal annealing for a long time. Further, another object of the present invention is to provide a method for improving a crystallization rate of an amorphous silicon layer using MILC as well as making a crystallization state of the crystallized silicon layer uniform.

According to a first aspect of the present invention for achieving the objects, there is provided a method of crystallizing an amorphous silicon layer by forming crystallization promoting material on at least a portion of the amorphous silicon layer and applying crystallization energy thereto, which comprises the step of implanting boron into the at least a portion of the amorphous silicon layer so as to promote a crystallization rate of the amorphous silicon layer, before applying the crystallization energy thereto.

According to a second aspect of the present invention, there is method of fabricating an N-type thin film transistor including a crystalline silicon active layer which is crystallized by forming crystallization promoting material on at east a portion of an amorphous silicon layer and applying crystallization energy thereto, which comprises the steps of implanting boron into the at least portion of the amorphous silicon layer before or after implanting N-type dopants into the amorphous silicon layer, and applying the crystallization energy to the amorphous silicon layer into which the boron has been implanted.

According to a third aspect of the present invention, there is a method of fabricating a P-type thin film transistor including a crystalline silicon active layer which is crystallized by forming crystallization promoting material on at least a portion of an amorphous silicon layer ad applying crystallization energy thereto, which comprises the steps of implanting boron into the at least portion of the amorphous silicon layer before or after implanting P-type dopants into the amorphous silicon layer, and applying the crystallization energy to the amorphous silicon layer into which the boron has been implanted.

According to a fourth aspect of the present invention, there is a method of fabricating a CMOS thin film transistor which is composed of P-type and N-type thin film transistors including each crystalline silicon active layer which is crystallized by forming crystallization promoting material on at least a portion of an amorphous silicon layer and applying crystallization energy thereto, which comprises the steps of implanting either boron or P-type dopants including the boron into the amorphous silicon layers of the P-type and N-type thin film transistors; implanting N-type dopants into the amorphous silicon layer after forming a mask on the amorphous silicon layer of the P-type thin film transistor; and applying the crystallization energy to the amorphous silicon layers of the P-type and N-type thin film transistors.

According to a fifth aspect of the present invention, there is a P-type or N-type thin film transistor including a crystalline silicon active layer which is crystallized by forming crystallization promoting material on at least a portion of an amorphous silicon layer and applying crystallization energy thereto, wherein the active layer is formed by crystallizing the amorphous silicon layer after implanting born into the at least portion of the amorphous silicon layer.

According to a sixth aspect of the present invention, there is a CMOS thin film transistor which is composed of P-type and N-type thin film transistors including each crystalline silicon active layer which is crystallized by forming crystallization promoting material on at least a portion of an amorphous silicon layer and applying crystallization energy thereto, wherein the active layers of the N-type and P-type thin film transistors are crystallized by applying the crystallization energy to the amorphous silicon layer after implanting boron into the amorphous silicon layer.

### BRIEF DESCRIPTION OF THE DRAWINGS

The above objects and features of the present invention will become apparent from the following description of preferred embodiments given in connection with the accompanying drawings, in which:

FIG. 1 is a graph illustrating rates of metal induced lateral crystallization (MILC) with respect to thermal annealing temperature in a case where phosphorus was implanted into silicon;

FIG. 2 is a graph illustrating the MILC rates with respect to the thermal annealing temperature in a case where boron was implanted into silicon;

FIGS. 3A and 3B are comparison tables of the crystallization rates when the phosphorus and boron are implanted into the silicon at different concentrations;

FIGS. 4A to 4F are sectional views showing a series of processes of fabricating a thin film transistor according to a preferred embodiment of the present invention;

FIGS. 5A to 5D are schematic sectional views showing a method of forming a metal layer induced by the MILC, which is used in the present invention;

FIGS. 6A to 6D are sectional views showing a series of processes of fabricating a thin film transistor according to another preferred embodiment of the present invention;

FIGS. 7A to 7D are sectional views showing a series of processes of fabricating a thin film transistor according to a further preferred embodiment of the present invention; and

FIGS. 8A to 8D are sectional views showing a series of processes of fabricating a CMOS transistor according to a still further preferred embodiment of the present invention.

### DETAILED DESCRIPTION OF THE INVENTION

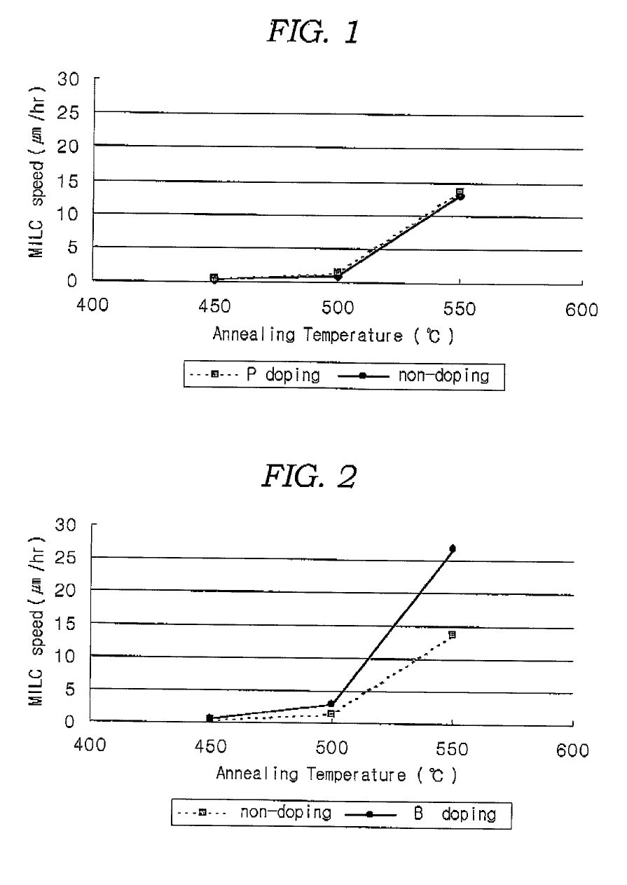

FIG. 1 is a graph illustrating a change of a MILC rate with respect to thermal annealing temperature in a case where phosphorus was implanted into silicon. In FIG. 1, an implanting concentration of the phosphorus is 1×10¹⁵/cm². As shown in FIG. 1, in a case where the thermal annealing temperature is 500° C., it is understood that the crystallization rate when implanting the phosphorus into the silicon is reduced as compared with that when not implanting the phosphorus into the silicon. At this time, the effect that the crystallization rate is reduced due to phosphorus implantation becomes remarkable as the concentration of the phosphorus to be implanted is increased. However, in a case where the thermal annealing temperature is 550° C., the MILC rate is hardly changed even when the phosphorus was implanted into the silicon. Therefore, it can be seen from FIG. 1 that an influence of the phosphorus on the MILC rate varies according to the temperature but is generally exerted to decrease the MILC rate. When the annealing temperature is increased, an influence of the phosphorus implantation on the crystallization rate is reduced. Even when the silicon is crystallized using the MIC, the above result is observed, and an influence of the annealing temperature on the crystallization rate is also similar to the case using the MIC.

FIG. 2 is a graph illustrating a change of the MILC rate with respect to the thermal annealing temperature in a case where boron was implanted into the silicon. In FIG. 2, an implanting concentration of the boron is 1×10¹⁵/cm². Contrary to the case where the phosphorus is implanted into the silicon as shown in FIG. 1, it is understood that the crystallization rate by means of the MILC when the boron was implanted into the silicon is greatly increased as compared with that when the boron was not implanted into the silicon. In addition, as the implanting concentration of the boron is increased, the crystallization rate of the silicon is further increased. Furthermore, contrary to the case where the phosphorus was implanted into the silicon, the above effect is still maintained even when the annealing temperature is increased. The effect of increasing the crystallization rate due to the boron implantation is also similarly obtained even when the silicon is crystallized using the MIC phenomenon.

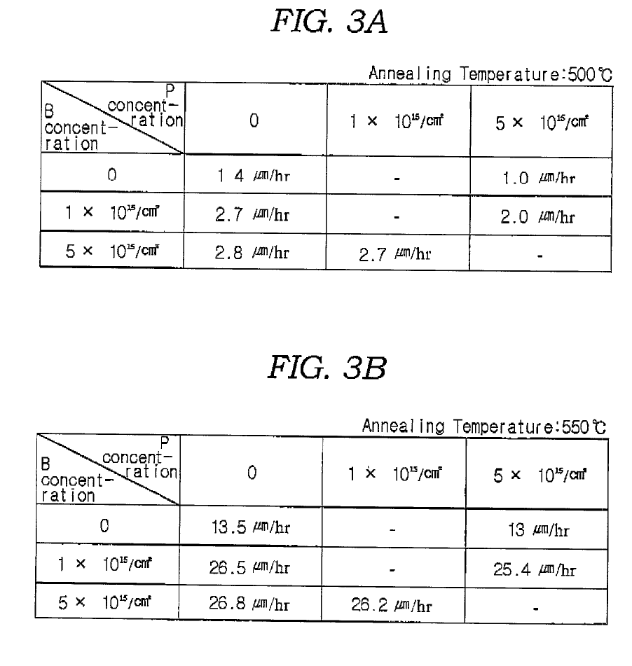

FIGS. 3A and 3B are comparison tables of the silicon crystallization rates at the annealing temperatures of 500° C. and 550° C., respectively, for the silicon crystallization when the phosphorus and boron were implanted into the silicon at predetermined concentrations. Referring to FIGS. 3A and 3B, it is understood that an influence of the implanted impurities on the MILC rate is mainly determined according to whether the boron was implanted into the silicon. In other words, when the boron is implanted into the silicon, the MILC rate Is greatly increased regardless of the thermal annealing temperature and the phosphorus implantation.

When the thermal annealing temperature is 500° C. as shown in FIG. 3A, the MILC rate of the intrinsic silicon is 1.4 μm/hr. Herein, the crystallization rate was decreased to 1.0 μm/hr when the phosphorus was implanted therein, whereas the rate was greatly increased to 2.7˜2.8 μm/hr regardless of boron concentrations when the boron was implanted therein. The boron's effect on the increase of the MILC rate is greatly produced even when the phosphorus is implanted at a higher concentration as compared with the boron. Thus, if the boron is implanted therein at the concentration of 1×10¹⁵/cm² while the phosphorus was implanted therein at the concentration of 5×10¹⁵/cm², the MILC rate becomes 2.0 μm/hr which is much faster than that of the intrinsic silicon.

Even in a case where the thermal annealing is performed at 500° C. as shown in FIG. 3B, it can be understood that the MILC rate is highly increased regardless of the phosphorus concentration when the boron was implanted into the silicon. In particular, if the thermal annealing temperature is increased to 550° C., the influence of the phosphorus on the crystallization rate is reduced and the effect of increasing the MILC rate due to the boron is further remarkable. For example, referring to the figure, if the boron is implanted into the silicon at a relatively low concentration of 1×10¹⁵/cm² while the phosphorus is implanted into the silicon at the higher concentration of 5×10¹⁵/cm², the MILC rate becomes twice as fast as the MILC rate of the intrinsic silicon. In addition, referring to both FIGS. 3A and 3B, it can be understood that the effect of increasing the MILC rate obtained when the boron is implanted at the concentration of 1×10¹⁵/cm² is similar to that obtained when the boron is implanted at the concentration of 5×10¹⁵/cm². In brief, the boron exerts a great influence on the MILC rate of the silicon regardless of its implanting concentration. Further, the influence of the phosphorus on the MILC rate is insignificant as compared with that of the boron and is much more decreased as the thermal annealing temperature is increased. Such an effect of increasing the crystallization rate due to boron implantation is also obtained similarly in the case where the silicon is crystallized using the MILC phenomenon.

As described above, the rate crystallization of the silicon using the MILC can be effectively controlled by means of the kinds and concentrations of the impurities implanted into the silicon, the thermal annealing temperature, and the like. Accordingly, this can cause the time required for crystallizing the active of the thin film transistor to be greatly reduced, and thus, the productivity of the semiconductor devices can also be greatly improved. Hereinafter, preferred embodiments of the method of fabricating the thin film transistor will be explained in detail with reference to the accompanying drawings.

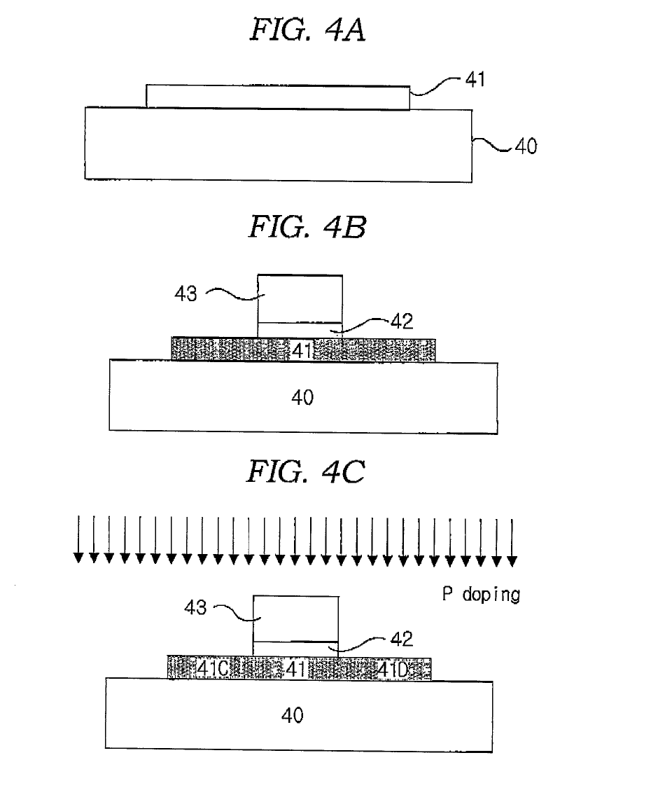

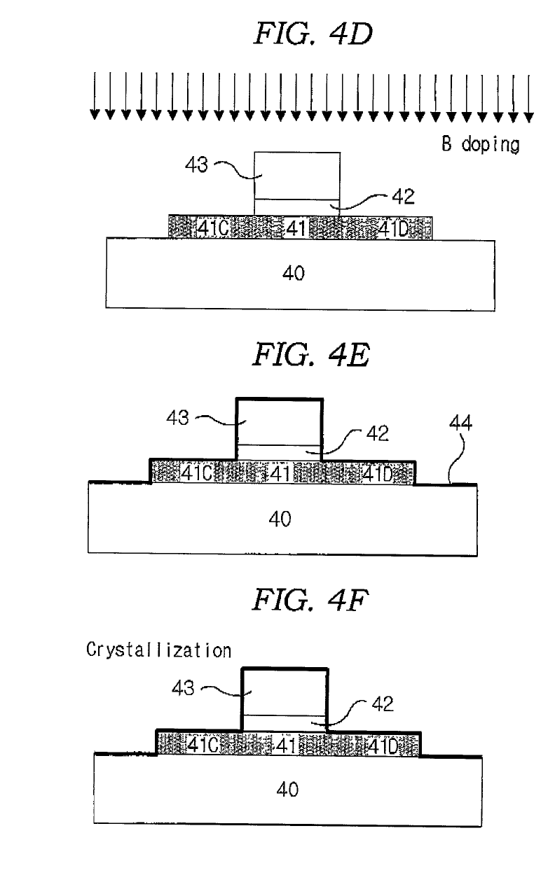

FIGS. 4A to 4F show section views showing a series of processes of fabricating an N-type or P-type thin film transistor according to preferred embodiment of the present invention. FIG. 4A is a sectional view showing the state where an amorphous silicon layer 41 for constituting an active layer of the film transistor is formed and then patterned on an insulating substrate 40. The substrate 40 may be composed of an insulating material such as Corning 1737 glass, quartz, or silicon oxide. Alternatively, a lower insulating layer (not shown) for preventing contamination materials from diffusing from the substrate into the active layer may be formed on the substrate. The lower insulating layer can be formed by performing deposition of silicon oxide (SiO₂), silicon nitride (SiNₓ), silicon oxynitride (SiOₓN_{y}) or the composite material thereof at temperature of about 600° C. or lower and to thickness of 300 to 10,000 Å, more preferably 500 to 3,000 Å, using a deposition method such as plasma-enhanced chemical vapor deposition (PECVD), low-pressure chemical vapor deposition (LPCVD), atmospheric pressure chemical vapor deposition (APCVD), or electron cyclotron resonance CVD (ECR-CVD). The active layer 41 can be formed by performing deposition of amorphous silicon to thickness of 100 to 3,000 Å, more preferably 500 to 1,000 Å using PRCVD, LPCVD or sputtering. The active layer comprises a source region, a drain region, a channel region, and an additional region where other devices/electrodes will be formed later. The active layer formed on the substrate is patterned to meet a specification of a TFT to be fabricated. The active layer is patterned through dry etching by means of plasma of an etching gas by employing patterns made using photolithography.

FIG. 4B is a sectional view of a structure in which a gate insulating layer 42 and a gate electrode 43 are formed on the substrate 40 and the patterned active layer 41. The gate insulating layer 42 is formed by performing deposition of silicon oxide (SiO₂), silicon nitride (SiNₓ), silicon oxynitride (SiOₓN_{y}) or the composite material thereof to thickness of 300 to 3,000 Å, more preferably 500 to 1,000 Å, using the deposition method such as PECVD, LPCVD, APCVD, or ECR-CVD. The gate electrode 43 is formed on the gate insulating layer in such a manner that a gate electrode layer is formed by depositing conductive material such as metal material or doped polysilicon onto the gate insulating layer to thickness of 1,000 to 8,000 Å, more preferably 2,000 to 4,000 Å, using the method such as sputtering, evaporation, PECVD, LPCVD, APCVD, or ECR-CVD, and that the deposited gate electrode layer is then patterned. The gate electrode is patterned through wet or dry etching by employing patterns made using the photolithography.

FIGS. 4C and 4D are views showing the processes of doping the source region 41S and the drain region 41D of the active layer by using the gate electrode as a mask. In a case where an N-type TFT is fabricated, dopants such as PH₃, P, and As are doped at a dose of about 1.0×10¹¹ to 1.0×10²²/cm³ preferably, 1.0×10¹⁵ to 1.0×10²¹/cm³) with energy of 10 to 200 keV preferably, 30 to 100 keV) using ion shower doping or ion implantation method (refer to FIG. 4C). For example, in a case where a junction portion having a weakly doped region or an offset region is formed in the drain region, additional doping processes may be employed. Thereafter, the boron is implanted at a concentration lower than implanting concentration of the dopants such as PH₃, P, and As (refer to FIG. 4D). Further, in a case where a P-type TFT is fabricated, dopants such as B₂H₆, B, and BH₃ are doped at a dose of 1.0×10¹¹ to 1.0×10²²/cm³ (preferably, 1.0×10¹⁴ to 1.0×10²¹/cm³) with energy of about 10 to 200 keV during the process of FIG. 4c and the boron implantation process of FIG. 4D can be omitted.

FIG. 4E is a sectional view showing the state where a metal layer 44 for inducing the MILC of the amorphous silicon constituting the active layer is applied to the source region 41S and the drain region 41D. As for metal for inducing the MILC of the amorphous silicon, nickel (Ni) or palladium (Pd) is preferably used, and Ti, Ag, Au, Al, Sn, Sb, Cu, Co, Cr, Mo, Tr, Ru, Rh, Cd, Pt and the like may also be used. The metal such as Ni or Pd for inducing the MILC can be applied to the active layer by means of the sputtering, evaporation, PECVD, or ion implantation method. However, the sputtering method is generally used. The thickness of the applied metal layer may be arbitrarily selected within the limits sufficient for inducing the MILC of the active layer, and is approximately 1 to 10,000 Å, preferably 10 to 200 Å.

FIG. 4F shows a process of activating the dopants implanted into the source and drain regions of the active layer along with inducing the crystallization of the active layer by forming and thermal annealing the MILC source metal layer 44. This process is performed by employing a rapid thermal annealing (RTA) method in which the materials are heated during a short period of time within several minutes at a temperature of about 700 or 800° C. using a tungsten-halogen or Xenon arc heating lamp, or an ELC method in which the materials are heated during a very short period of time using an excimer laser beam. Further, the materials may be heated using the microwave. In the embodiment, it is preferable and effective to utilize the method of crystallizing the active layer by using the MILC capable of crystallizing the amorphous silicon at the temperature of 300 to 600° C. lower than that used in the RTA method. The crystallization of the active layer is preferably performed in a furnace at a temperature of 300 to 700° C. during 0.1 to 50 hours, more preferably during 0.5 to 20 hours. During the thermal annealing process, in case of the P-type TFT, the crystallization rate of the amorphous silicon is increased by the boron implanted therein as described above in connection with FIGS. 3A and 3B. Even when the N-type TFT is fabricated, the crystallization is promoted by the boron additionally implanted during the process of FIG. 4D separately from the N-type impurities. Thus, the time required for the crystallization can be greatly reduced as compared with the case where the boron is not implanted. As described above in connection with FIGS. 3A and 3B, the dopants such as P or As implanted for fabricating the N-type TFT do not exert a great influence on the effect that the crystallization is promoted by the boron.

Thereafter, a contact insulating layer is formed and patterned to form contact holes. The contact insulating layer is formed by performing deposition of silicon oxide, silicon nitride, silicon oxynitride or the composite material thereof to thickness of 1,000 to 15,000 Å, more preferably 3,000 to 7,000 Å, using the deposition method such as PECVD, LPCVD, APCVD, and ECR-CVD. The contact insulating layer is wet or dry etched by employing patterns, which are made by the photolithography, as a mask so as to form the contact holes for providing paths through which contact electrodes are connected to the source and drain regions of the active layer. After the contact insulating layer and the contact holes have been formed, the transistor is fabricated according to the conventional method.

According to the method of the present invention, even when the N-type TFT is fabricated the MILC rate can be increased by additionally implanting the boron into the amorphous silicon, and thus, the processing time for fabricating the TFT can be greatly reduced. Further, even when the P-type TFT is fabricated, the crystallization rate can be improved by appropriately controlling the concentration of the boron to be implanted. Contrary to a process order described in connection with FIGS. 4A to 4F, the processes of doping the phosphorus and boron may be performed in a reverse order, and the processes of forming the MILC-inducing metal layer and implanting the impurities may also be carried out in a reverse order.

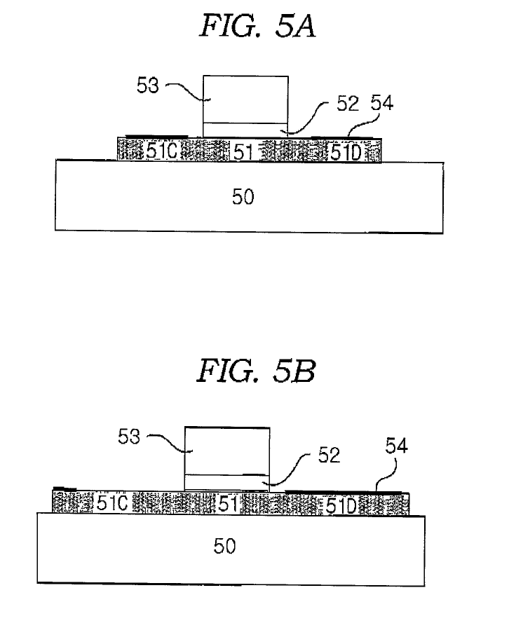

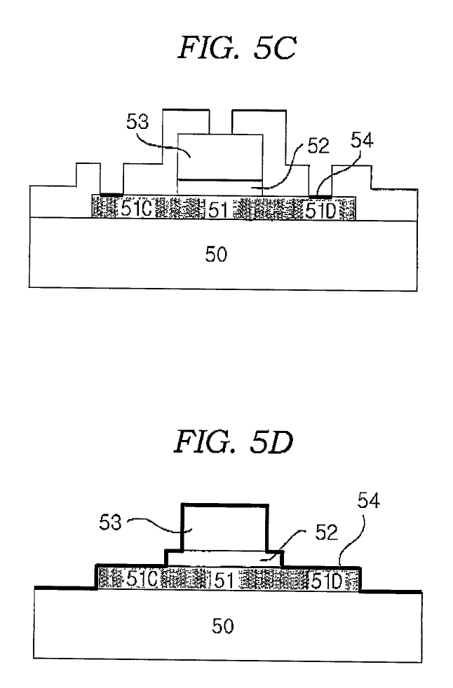

FIGS. 5A to 5D illustrate various configurations of the MILC source metals formed during the process of FIG. 4E. The MILC source metal 54 may be formed to be offset from the gate insulating layer 52 and the gate electrode 53 as shown in FIG. 5A, or to be located asymmetrically with respect to the gate insulating layer and the gate electrode as shown in FIG. 5B. Furthermore, as show in FIG. 5C, the MILC source metal may be formed on the active layer by using the contact holes. Alternatively, as shown in FIG. 5D, the MILC source metal may be formed to be offset from the channel region below the gate electrode 53 through the gate insulating layer which is patterned to be wider than the gate electrode 53.

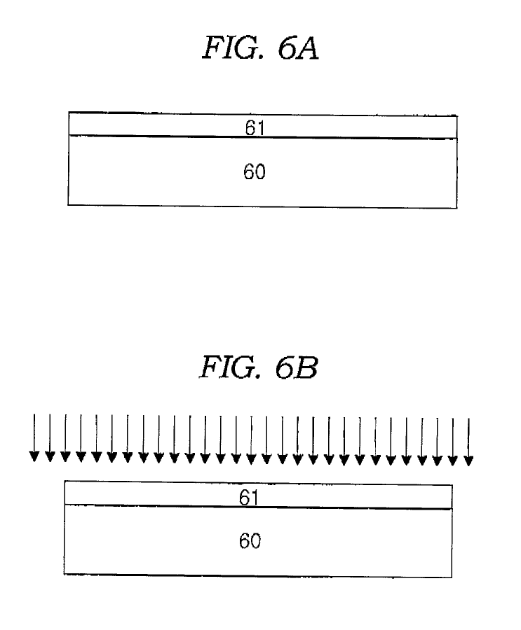

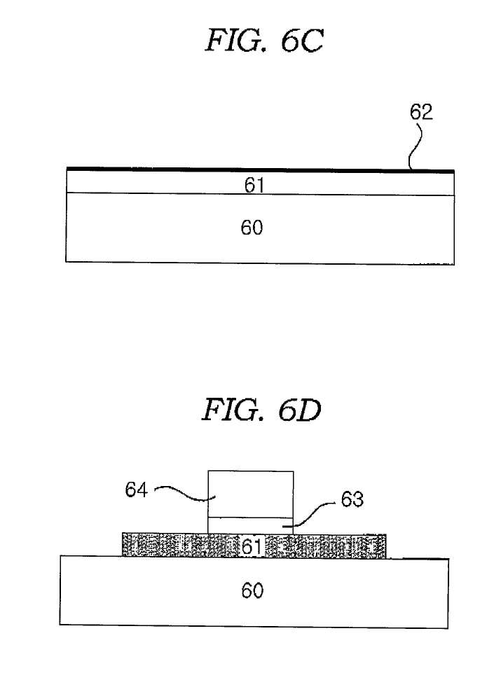

FIGS. 6A to 6D are sectional views showing the processes of fabricating a thin film transistor according to another preferred embodiment of the present invention. FIG. 6A is a sectional view showing the state where an amorphous silicon layer 61 for constituting an active layer of the thin film transistor is formed on an insulating substrate 60. Boron may be implanted into the amorphous silicon layer at a low concentration of about 1×10¹³/cm², as shown in FIG. 6B. Alternatively, the amorphous silicon layer may be formed to contain such a concentration of the boron upon formation thereof. In such a case, the process of FIG. 6B can be omitted. Then, as shown in FIG. 6C, an MILC source metal 62 is deposited onto an entire surface of the active layer. Thereafter, the thermal annealing process for crystallizing the active layer is performed in the same method as described in connection with FIG. 4F. At this time, the crystallization rate of the active layer, which is induced by the MILC source metal 62 deposited onto the active layer, is increased due to the boron component implanted into or contained in the active layer 61. Thus, the thermal annealing time can be remarkably reduced as compared with the case where no boron is implanted into the active layer. Thereafter, as shown in FIG. 6D, the crystallized active layer 61 is patterned, and a gate insulating layer 63, a gate electrode 64 and the like are formed onto the patterned active layer. Finally, the thin film transistor is fabricated according to the conventional method.

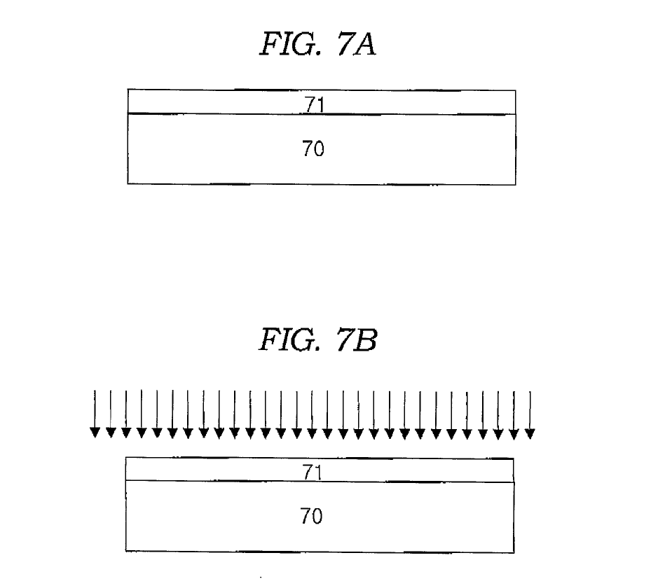

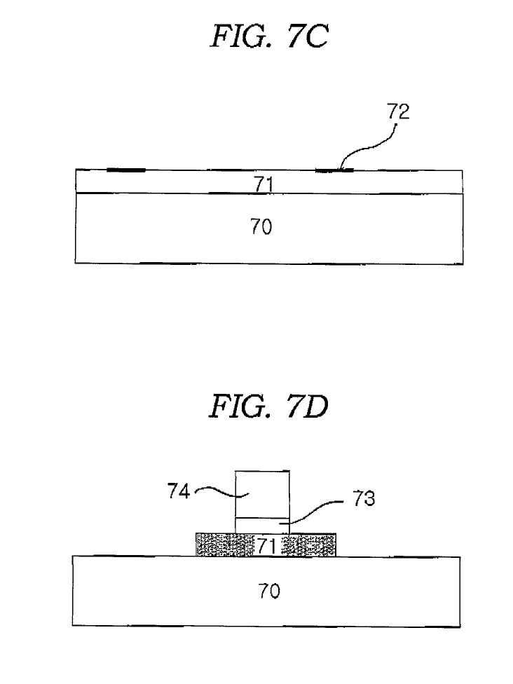

FIGS. 7A to 7D are sectional views showing the processes of fabricating a thin film transistor according to a further preferred embodiment of the present invention. FIG. 7A is a sectional view showing the state where an amorphous silicon layer 71 for constituting an active layer of the thin film transistor is formed on an insulating substrate 70. Boron may also be implanted into the amorphous silicon layer at a low concentration of about 1×10¹³/cm², in the same way as shown in FIG. 6B. Alternatively, the amorphous silicon layer may be formed to contain such a concentration of the boron upon formation thereof. In such a case, the process of FIG. 7B can be omitted. Then, as shown in FIG. 7C, an MILC source metal 72 is deposited onto a part of the amorphous silicon layer (i.e., an active layer). Thereafter, the thermal annealing process for crystallizing the active layer is performed in the same method as described in connection with FIG. 4F. At this time, in a region of the active layer where the MILC source metal 72 is deposited, the crystallization is performed by the MIC. On the other hand, in a region of the active layer where the MILC source metal is not deposited, the crystallization is performed by the MILC propagating from the region where the MILC source metal is deposited. The crystallization rate by means of the MIC or MILC is increased due to the boron component implanted into or contained in the active layer. Thus, the thermal annealing time can be remarkably reduced as compared with the case where no boron is implanted into the active layer. After the crystallization of the active layer, as shown in FIG. 7D, the crystallized active layer is patterned, and a gate insulating layer 73, a gate electrode 74 and the like are formed onto the patterned active layer. Finally, the thin film transistor is fabricated according to the conventional method.

As described in FIGS. 6A to 6D and FIGS. 7A to 7D, in a case where the N-type TFT is fabricated, there is no problem although the boron is implanted onto the entire surface of the amorphous silicon layer. However, in a case where the P-type TFT is fabricated, a phenomenon that leakage current is increased due to the boron implanted into the active layer corresponding to a region other than the channel region may occur. Nevertheless, this problem is generally insignificant because the concentration of the boron, which is doped for increasing the crystallization rate, is very low. Moreover, if the TFT is employed in a driving circuit in which the leakage current is insignificant, there in no problem.

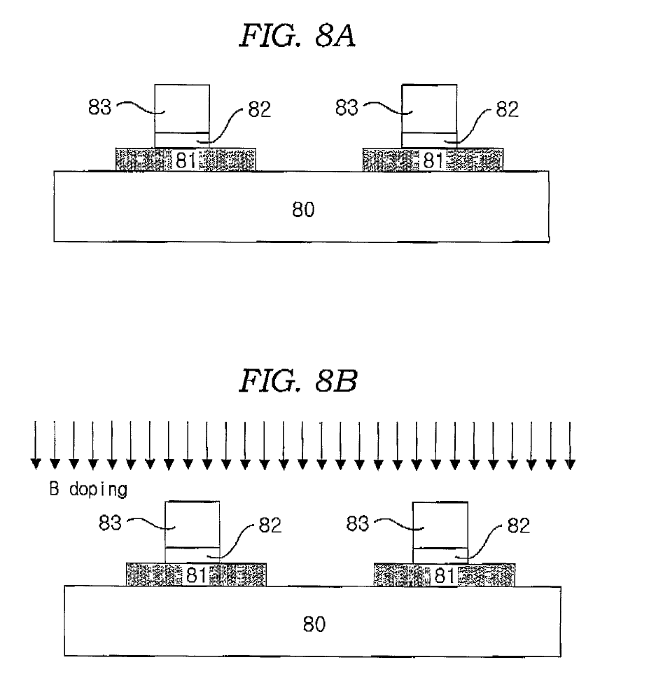

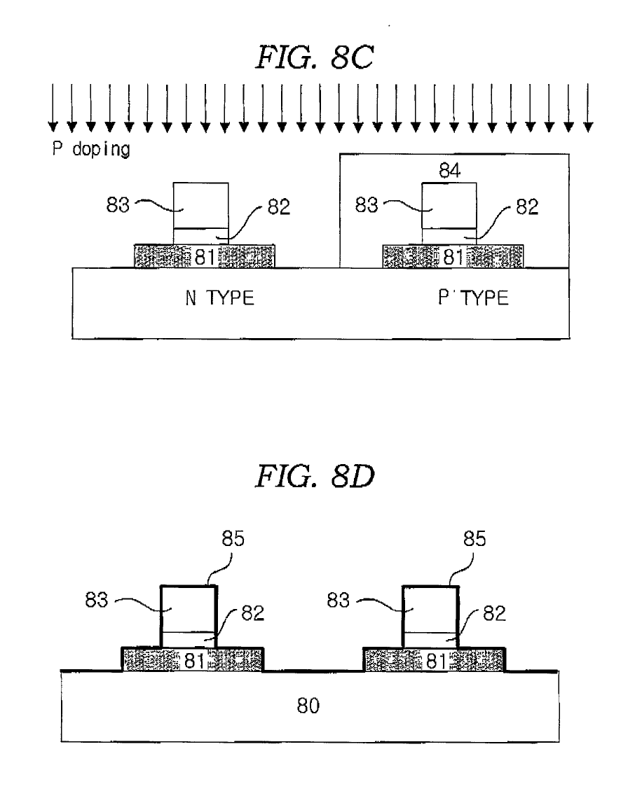

FIGS. 8A to 8D are sectional views showing the processes of fabricating a CMOS transistor according to a still further preferred embodiment of the present invention. In order to form a CMOS structure, amorphous silicon layers 81 are formed on an insulating substrate 80 and then patterned in a desired shape, as shown in FIG. 8A. Then, gate insulating layers 82 and gate electrodes 83 are formed on the amorphous silicon layers 81 according to the conventional method. Thereafter, as shown in FIG. 8B, the boron is implanted into the amorphous silicon layers 81 at a concentration of about 3×10¹⁵/cm² by using each of the gate electrodes as a mask. As shown in FIG. 8C, a portion where the P-type TFT will be fabricated is masked by a photoresist 84 and the like, and the phosphorus is then implanted into the portion at a high concentration of about 5×10¹⁵/cm². As shown in FIG. 8D, a MILC source metal 85 is formed on an entire surface of the substrate after removing the mask. The thermal annealing process for crystallizing the active layers of the N-type and P-type TFTs is performed in Me same method as described in connection with FIG. 4F. At this time, on the same grounds as described above, the crystallization rate of the active layers of the N-type and P-type TFTs is increased due to the boron component implanted into the active layers of these TFTs. Thus, the thermal annealing time can be remarkably reduced. Accordingly, it is apparent that the principle of the present invention can also be applied to the fabrication of the CMOS transistor.

According to the present invention, by implanting a relatively low concentration of the boron into the amorphous silicon, the crystallization rate of the amorphous silicon can be greatly increased regardless of the concentration and implantation of other impurities when the amorphous silicon for constituting the active layer of the thin film transistor is crystallized using the MIC or MILC phenomenon. Thus, there are advantages in that the time required for the thermal annealing for crystallizing the active layer of the thin film transistor can be greatly reduced, and thus, the productivity thereof can also be enhanced. Further, there is an advantage in that the thermal annealing time for the crystallization can be remarkably reduced during the process of fabricating all kinds of thin film transistors (TFTs) such as N-type, P-type and CMOS TFTs.

Although the present invention has been described with respect to the preferred embodiments thereof, the embodiments are only examples of the present invention and should not be construed as limiting the scope of the present invention. Accordingly, the scope of the present invention covers the scope of the invention defined by the appended claims, and it should be understood that a person having an ordinary skill in the art to which the present invention pertains can make various modifications and changes thereto without departing from the spirit and scope of the invention defined by the claims.

What is claimed is:

1. A method of crystallizing an amorphous silicon layer by forming crystallization promoting material on at least a portion of the amorphous silicon layer and applying crystallization energy thereto, comprising the step of:
implanting boron into the at least a portion of the amorphous silicon layer so as to promote a crystallization rate of the amorphous silicon layer, before applying the crystallization energy thereto.

2. The method as claimed in claim 1, wherein the crystallization promoting material includes at least one material selected from a group consisting of Ni, Pd, Ti, Ag, Au, Al, Sn, Sb, Cu, Co, Cr, Mo, Tr, Ru, Rh, Cd, and Pt.

3. The method as claimed in claim 1, wherein furnace annealing, laser annealing, rapid thermal annealing (RTA), line RTA, or microwave annealing is used to apply the crystallization energy.

4. The method as claimed in claim 1, wherein the boron is implanted at a concentration of 1.0×10¹³/cm² or higher.

5. A method of fabricating an N-type thin film transistor including a crystalline silicon active layer which is crystallized by forming crystallization promoting material on at least a portion of an amorphous silicon layer and applying crystallization energy thereto, comprising the steps of:
implanting boron into the at least portion of the amorphous silicon layer before or after implanting N-type dopants into the amorphous silicon layer; and
applying the crystallization energy to the amorphous silicon layer into which the boron has been implanted.

6. The method as claimed in claim 5, wherein the crystallization promoting material includes at least one material selected from a group consisting of Ni, Pd, Ti, Ag, Au, Al, Sn, Sb, Cu, Co, Cr, Mo, Tr, Ru, Rh, Cd, and Pt.

7. The method as claimed in claim 5, wherein furnace annealing, laser annealing, rapid thermal annealing (RTA), line RTA, or microwave annealing is used to apply the crystallization energy.

8. The method as claimed in claim 5, wherein doping concentration of the boron is lower than that of the N-type dopants implanted into the amorphous silicon layer.

9. A method of fabricating a P-type thin film transistor including a crystalline silicon active layer which is crystallized by forming crystallization promoting material on at least a portion of an amorphous silicon layer and applying crystallization energy thereto, comprising the steps of:
implanting boron into the at least portion of the amorphous silicon layer before or after implanting P-type dopants into the amorphous silicon layer; and
applying the crystallization energy to the amorphous silicon layer into which the boron has been implanted.

10. The method as claimed in claim 9, wherein the P-type dopants include the boron, and thus, the step of implanting the boron into the amorphous silicon layer is omitted.

11. The method as claimed in claim 9, wherein the crystallization promoting material includes at least one material selected from a group consisting of Ni, Pd, Ti, Ag, Au, Al, Sn, Sb, Cu, Co, Cr, Mo, Tr, Ru, Rh, Cd, and Pt.

12. The method as claimed in claim 9, wherein furnace annealing, laser annealing, rapid thermal annealing (RTA), line RTA, or microwave annealing is used to apply the crystallization energy.

13. A method of fabricating a CMOS thin film transistor which is composed of P-type and N-type thin, film transistors including each crystalline silicon active layer which is crystallized by forming crystallization promoting material on at least a portion of an amorphous silicon layer and applying crystallization energy thereto, comprising the steps of:
implanting either boron or P-type dopant including the boron into the amorphous silicon layers of the P-type and N-type thin film transistors;
implanting N-type dopants into the amorphous silicon layer after forming a mask on the amorphous silicon layer of the P-type thin film transistor; and
applying the crystallization energy to the amorphous silicon layers of the P-type and N-type thin film transistors.

14. The method as claimed in claim 13, wherein the crystallization promoting material includes at least one material selected from a soup consisting of Ni, Pd, Ti, Ag, Au, Al, Sn, Sb, Cu, Co, Cr, Mo, Tr, Ru, Rh, Cd, and Pt.

15. The method as claimed in claim 13, wherein furnace annealing, laser annealing, rapid thermal annealing (RTA), line RTA, or microwave annealing is used to apply the crystallization energy.

16. A P-type or N-type thin film transistor including a crystalline silicon active layer which is crystallized by forming crystallization promoting material on at least a portion of an amorphous silicon layer and applying crystallization energy thereto, being characterized in that:
the active layer is formed by crystallizing the amorphous silicon layer after implanting born into the at least portion of the amorphous silicon layer.

17. The thin film transistor as claimed in claim 16, wherein the crystallization promoting material includes at least one material selected from a group consisting of Ni, Pd, Ti, Ag, Au, Al, Sn, Sb, Cu, Co, Cr, Mo, Tr, Ru, Rh, Cd, and Pt.

18. The method as claimed in claim 16, wherein furnace annealing, laser annealing, rapid thermal annealing (RTA), line RTA, or microwave annealing is used to apply the crystallization energy.

19. A CMOS thin film transistor which is composed of P-type and N-type thin film transistors including each crystalline silicon active layer which is crystallized by forming crystallization promoting material on at least a portion of an amorphous silicon layer and applying crystallization energy thereto, being characterized in that:
the active layers of the N-type and P-type thin film transistors are crystallized by applying the crystallization energy to the amorphous silicon layer after implanting boron into the amorphous silicon layer.
